(19) United States
(12) Patent Application Publication
(10) Pub. No.: US 2017/0040247 A1
(43) Pub. Date: Feb. 9, 2017

(54) SUBSTRATE CORE WITH EFFECTIVE THROUGH SUBSTRATE VIAS AND METHOD FOR MAKING THE SAME

(71) Applicant: Yuci Shen, Cupertino, CA (US)

(72) Inventor: Yuci Shen, Cupertino, CA (US)

(21) Appl. No.: 14/821,732

(22) Filed: Aug. 8, 2015

(51) Int. Cl. H01L 23/498; H01L 21/78; H05K 1/03; H01L 21/48

(52) U.S. Cl. CPC H01L 23/49827; H01L 23/49822; H01L 23/49894; H01L 23/49838; H01L 21/4857; H01L 21/486; H01L 21/4853; H01L 21/78; H05K 1/0306; H05K 1/0313

(57) ABSTRACT

The disclosure describes a panel of substrate core including a plurality of substrate core units, each having a pattern of effective through substrate vias (eTSV). The substrate core unit comprises a dielectric core layer, a plurality of dark through core vias (dTCV) embedded and distributed in the dielectric core layer and passing through the dielectric core layer from its upper to lower surfaces, and a pattern of eTSV; wherein the locations of the plurality of dTCV may not be defined, and the pattern of eTSV are precisely defined and formed through two metal layers, two dielectric layer with openings at desired locations and a portion of the plurality of dTCV. The material for the dielectric core layer may be ceramic, glass or organic material. The present method may make any desired thickness of ceramic or glass substrate core having a pattern of eTSV with small size and pitch of eTSV.

### TECHNICAL FIELD OF THE INVENTION

The disclosure relates generally to integrated circuit (IC) semiconductor packaging technology, and particularly to technologies for producing a substrate core having through substrate vias (TSV), which are used in further producing a substrate for packaging IC chips or electric devices.

### BACKGROUND OF THE INVENTION

A substrate is a bridge connecting two or more IC chips or electric devices with a fine pitch of electric contact pads to another substrate or a board with a coarse pitch of electric contact pads. For a substrate with core, a through substrate via (TSV) is an electrically conductive path completely through the core for connecting the metal or circuit layers on both surfaces of the core. The material for the substrate core may include silicon, glass, ceramic or organic material. A type of substrates with silicon or glass core used for 2.5D or 3D IC chip package are recently developed, called silicon TSV (through silicon via) interposer or glass TGV (through glass via) interposer, where the silicon TSV interposer or glass TGV interposer may connect multiple IC chips with fine pitch mounted on its top surface to a substrate with a coarse pitch. The silicon TSV and glass TGV interposers have the similar structure in geometry as a substrate with core, that is, they comprise a core layer, a pattern of through core vias, one or more circuit layers and one or more dielectric layers and one terminal layer on each surface of the core layer. The manufacture in prior arts for a substrate with core and a silicon TSV or glass TGV interposer comprises the basic processing steps: 1) prepare a panel of core (a rectangular piece of organic material, a circular silicon wafer or glass wafer, for example); 2) form a pattern of through core vias in each core unit (a panel of core includes a plurality of core units for producing a plurality of substrates in a batch); 3) stack one or more circuit layers and one or more dielectric layers and one terminal layer on each surface of the panel of core so as to form a panel of substrate including a plurality of substrate units, each for an IC chip package.

There are two types of methods described in prior arts for producing a pattern of through core vias in each substrate core unit of a panel of substrate core. The first type of method may be classified as a micro-level method, wherein each through core via is precisely produced including its size and location by an opening and filling process in which a pattern of holes are first opened by mechanical drilling, laser drilling or etching, and then the holes are filled by a conductive material, like copper. The second type of method may be classified as a macro-level method, wherein a column of dielectric material with metal wires is first formed, and then the column is sliced into a plurality of pieces so as to form a plurality of substrate core units with a plurality of through core vias.

The advantage of the micro-level method is that a pattern of through core vias with any irregular distributed vias may be precisely made. And the disadvantage of the micro-level method is that 1) the cost is high, and 2) the via size is limited by the core thickness. For example, it is very difficult or expensive to produce a small via size (like 20 um in diameter or smaller) of through core via in a thick (like 0.4 mm or thicker) glass or ceramic core. The advantage of the macro-level method is that 1) the cost is low, and 2) the via size is not limited by the core thickness. For example, it is easy to produce a small via size (like 20 um in diameter or smaller) of through core via in any thick (like 0.4 mm or thicker) glass or ceramic core. However, the disadvantage of the macro-level method is that 1) it is difficult to produce a pattern of through core vias with irregularly distributed vias because it is not easy to form and fix a pattern of irregularly distributed metal vias in a dielectric material column, and 2) it is a challenge for precisely positioning the locations of through core vias because the metal wires in a dielectric material column may move during its solidification, like during the co-firing process of a ceramic column with metal wires.

It is noted that in prior arts, when an IC package substrate is produced based on a substrate core with through core vias (TCV), the metal or circuit layer deposited over the through core vias are directly connected with the through core vias. For getting the direct connection between the through core vias and the metal or circuit layer, the locations of the through core vias have to be precisely defined. For the through core vias produced by the micro-level method, the locations of the through core vias have been precisely defined. But for the through core vias produced by the macro-level method, the locations of the through core vias may not be precisely defined. However, in prior arts, even though the substrate core with through core vias based on the macro-level method (like a glass body with metal wires) may be adopted, the conventional concept, i.e., the direct connection between the through core vias and the metal or circuit layer are still adopted for producing IC package substrates. In fact, it is a big challenge to get a direct connection between the through core vias produced by the macro-level method and the metal or circuit layer deposited over the through core vias because the locations of the through core vias produced by the macro-level method may not be precisely defined, especially for a pattern of through core vias having an irregular via distribution.

In order to take the advantages of the micro-level method and the macro-level method for producing a substrate core with through core vias in a low cost, an inventive concept, that is, effective through core via (eTSV) is described in the present invention. Furthermore, a substrate core with effective through core vias and method for making the same are disclosed. As an example, a very thick glass or ceramic core with a pattern of effective through core vias having any irregular via distribution may be efficiently produced according to the present invention.

### SUMMARY OF THE INVENTION

The purpose for using a through core via in a substrate core is to electrically connect a pair of locations on the upper and lower surfaces of the substrate core so that the circuits on the upper and lower surfaces of the substrate core may get communication with each other. It is noted that how the two locations on the upper and lower surfaces of the substrate core are electrically connected is in fact not required in a specific application of a substrate core. In prior arts, a pattern of precisely positioned through core vias are produced to electrically connect a corresponding pattern of locations on the upper and lower surfaces of a substrate core. In the present invention, a pattern of precisely positioned eTSV (effective through core vias) are produced for the same purpose, wherein the pattern of precisely positioned effective through core vias are formed through a plurality of dark through core vias, two metal layers, and two dielectric layers having a pattern of openings. It is noted that the pattern of openings in each dielectric layer is precisely produced using a micro-level method (like laser drilling or etching) for precisely defining the pattern of effective through core vias, while the plurality of dark through core vias are produced using a macro-level method (like the method through a dielectric material column with metal wires) wherein the positions of the dark through core vias are not required to be precisely defined, here named dark through core vias (dTCV). According to the present invention, it is only needed to precisely produce a pattern of opening in a very thin dielectric layer (like 1 um thickness or about) using a micro-level method. The present invention provides an efficient solution for producing a substrate core with through core vias as compared to prior arts wherein a pattern of through core vias completely passing through the whole substrate core need to be precisely produced. Furthermore, the manufacture of an IC package substrate is conventionally based on a panel of core, which is a homogeneous piece of dielectric material in prior arts, like a circular silicon or glass wafer or a rectangular panel of organic material. A panel of substrate core is adopted for producing a plurality of IC package substrate units in a batch way. In the present invention, a panel of inhomogeneous core layer consisting of a plurality of dielectric core units connected through a panel of matrix material is introduced, wherein each dielectric core unit has a plurality of dark through core vias, and the size of the dielectric core units is defined according to the size of an IC package substrate for a specific application.

In one preferred embodiment of the present invention, a method for making a panel of substrate core with effective through substrate vias is described, comprising the key manufacturing steps: a) providing a plurality of dielectric material columns, wherein each dielectric material column includes a plurality of embedded metal wires, the plurality of embedded metal wires align in the longitudinal direction of the dielectric material columns and the locations of the embedded metal wires may be dark; b) integrating the plurality of dielectric material columns into an ingot of dielectric material columns by using a matrix material to encase and connect the plurality of dielectric material columns from their sides; c) slicing the ingot of dielectric material columns along the direction perpendicular to the embedded metal wires into a plurality of pieces so as to form a plurality of inhomogeneous core layers with each including a plurality of dielectric core units, each dielectric core unit including a plurality of dark through core vias (dTCV), wherein the locations of the plurality of dTCV may be dark; d) stacking two metal layers with each on one surface of the inhomogeneous core layer; e) removing some portions of the two metal layers to form a desired number of regional metal pieces in each region corresponding to each dielectric core unit; wherein the regional metal pieces on the upper surface and the regional metal pieces on the lower surface align with each other, forming a desired number of pairs of regional metal pieces, each pair of regional metal pieces have the same size and shape, align with each other from upper and lower surfaces of each dielectric core unit, the size of each pair of regional metal pieces is bigger than the space among the dTCV embedded and distributed in each dielectric core unit so that each pair of regional metal pieces are electrically connected by at least one dTCV, the space between any two neighboring regional metal pieces on the same surface is bigger than the size of each dTCV so that any two neighboring regional metal pieces are not electrically connected by the same dTCV, the location of each pair of regional metal pieces is determined according to the location of each desired eTSV; f) stacking two dielectric layers with each on one surface of the inhomogeneous core layer, covering all the regional metal pieces; and g) forming a pattern of openings in each region of the two dielectric layers corresponding to each dielectric core unit so as to expose a portion of each regional metal piece, each pair of exposed metals corresponding to each pair of regional metal pieces form an effective through core via (eTSV) at the desired location, each eTSV is an electrically conductive path from the upper to lower surfaces of the panel of substrate core, resulting in a panel of substrate core having a plurality of substrate core units and each substrate core unit having a desired pattern of eTSV.

In another preferred embodiment of the present invention, a panel of substrate core with effective through substrate vias is described, comprising: 1) an inhomogeneous core layer consisting of a plurality of dielectric core units and a panel of matrix material, wherein each dielectric core unit is a piece of square or rectangular dielectric material having two surfaces and four sides, the plurality of dielectric core units are embedded in the panel of matrix material with the two surfaces of each dielectric core unit exposed in the two surfaces of the inhomogeneous core layer, and the shape of the panel of substrate core is defined by the shape of the panel of matrix material; 2) a plurality of dark through core via (dTCV) embedded and distributed in each of the dielectric core unit, wherein each dTCV is an electrically conductive via passing through the dielectric core unit from its upper to lower surfaces, and the locations of the dTCV may be dark; and 3) a pattern of effective through substrate via (eTSV) in each region corresponding to each dielectric core unit, forming a desired pattern of electrically conductive paths from the upper to lower surfaces of the substrate core corresponding to each region of each dielectric core unit, wherein the pattern of eTSV are formed through a portion of the plurality of dTCV, two metal layers and two dielectric layers having a pattern of openings in each layer.

An illustrative example of a substrate core unit with a pattern of eTSV and a panel of substrate core including a plurality of substrate core units according to the present invention is schematically showed in FIG. 5 and FIG. 6. A specific example of a substrate core unit with a pattern of eTSV may be made according to the present invention is described as: the material for the substrate core is low temperature co-fired ceramic (LTCC), the core thickness is about 0.3 mm to 0.5 mm for further producing a ceramic TSV interposer or about 0.8 mm for further producing a large IC chip package substrate with ceramic core, the via size of eTSV is about 10 um to 30 um for a ceramic TCV interposer or about 50 um to 100 um for a large IC chip package substrate with ceramic core, and the pitch among the eTSV is about 100 um to 200 um. It is known that it is very difficult or expensive for prior arts to make such a ceramic substrate core with a pattern of through core vias.

One advantage of the present invention is that a substrate core unit with a pattern of through substrate vias may be produced in a low cost. The second advantage is that the substrate core material may be ceramic, glass or organic material. And more advantages of the present invention include that a thick substrate core with a small via diameter and fine via pitch may be achieved.

The key idea in the present invention is to produce a pattern of effective through core vias by using a macro-micro hybrid method which is a combination of the macro-level method where a plurality of dark through core vias are produced through a dielectric material column with metal wires and the micro-level method where a pattern of openings in a very thin dielectric layer are precisely produced by drilling or etching process. And the key inventive concepts in the substrate core according to the present invention include 1) the dark through core vias (which may be produced by a macro-level method with a low cost) are adopted, wherein their precise locations are not required, and only a portion of all the dark through core vias may be active, and the remaining portion of all the dark through core vias are kept dummy, 2) a number of pairs of regional metal pieces are adopted to activate a portion of all the dark through core vias for forming the effective through core vias, 3) two dielectric layers with a desired pattern of openings (the openings in the dielectric layers may be produced by a micro-level method with a low cost) are adopted for precisely defining the locations and sizes of each effective through core via. More features, advantages and inventive concepts of the present invention are described with reference to the detailed description of the embodiments of the present invention below.

### BRIEF DESCRIPTION OF THE DRAWINGS

FIG. 1-1E are schematic diagrams for illustrating the basic features for producing an IC package substrate, including a homogeneous panel of substrate core, a pattern of through core vias, the structure of a through core via, and the usage of the through core vias when making an IC package substrate of prior arts.

FIG. 2 is a schematic diagram for illustrating a dielectric material column with metal wires and dielectric core units with dark through core vias of one embodiment of the present invention.

FIG. 2A is a schematic diagram for illustrating an ingot of dielectric material columns for producing a panel of inhomogeneous core layer including a plurality of dielectric core units, each having a plurality of dark through core vias of one embodiment of the present invention.

FIGS. 3 and 3A are schematic diagrams for illustrating a rectangular shape of a panel of inhomogeneous core layer including a plurality of dielectric core units, each having a plurality of dark through core vias, and a circular shape of a panel of inhomogeneous core layer including a plurality of dielectric core units, each having a plurality of dark through core vias of one embodiment of the present invention.

FIG. 4 is a schematic diagram for illustrating the structure of a plurality of dark through core vias embedded and distributed in a dielectric core unit of one embodiment of the present invention.

FIG. 4A is a schematic diagram for illustrating two metal layers stacked over each surface of a dielectric core unit as illustrated in FIG. 4 of one embodiment of the present invention.

FIG. 4B is a schematic diagram for illustrating a pattern of locations where a pattern of effective through substrate vias are desired of one embodiment of the present invention.

FIG. 4C is a schematic diagram for illustrating a number of regional metal pieces formed by removing some portions of the two metal layers according to the pattern of locations as illustrated in FIG. 4B of one embodiment of the present invention.

FIG. 4D is a schematic diagram for illustrating a number of regional metal pieces formed by removing some portions of the two metal layers according to the pattern of locations as illustrated in FIG. 4B, where the regional metal pieces are formed as big as possible of one embodiment of the present invention.

FIG. 4E is a schematic diagram for illustrating two dielectric layers stacked over the number of regional metal pieces as illustrated in FIGS. 4C and 4D of one embodiment of the present invention.

FIG. 5 is a schematic diagram for illustrating a substrate core unit having a pattern of eTSV of one embodiment of the present invention.

FIG. 5A is a schematic diagram for illustrating a substrate core unit having a pattern of eTSV of one embodiment of the present invention.

FIG. 6 is a schematic diagram for illustrating a rectangular panel of substrate core including a plurality of substrate core units, each having a pattern of eTSV of one embodiment of the present invention.

FIG. 6A is a schematic diagram for illustrating a circular panel of substrate core including a plurality of substrate core units, each having a pattern of eTSV of one embodiment of the present invention.

FIG. 7 is a schematic diagram for illustrating an IC package substrate based on the substrate core unit with a pattern of eTSV of one embodiment of the present invention.

FIG. 8 is a schematic diagram for illustrating a dielectric core unit as illustrated in FIG. 4 with two dielectric layers stacked over each surface and a pattern of locations where a pattern of eTSV are desired of another embodiment of the present invention.

FIG. 8A is a schematic diagram for illustrating a pattern of openings in the two dielectric layers according to the pattern of locations as illustrated in FIG. 8 where a pattern of eTSV are desired of another embodiment of the present invention.

FIG. 8B is a schematic diagram for illustrating two metal layers being stacked over the two dielectric layers as illustrated in FIG. 8A, covering and filling the openings of the two dielectric layers of another embodiment of the present invention.

FIG. 8C is a schematic diagram for illustrating the two metal layers as illustrated in FIG. 8B being processed as a pattern of eTSV and a circuit layer of another embodiment of the present invention.

FIG. 8D is a schematic diagram for illustrating an IC package substrate having the substrate core unit with a pattern of eTSV as illustrated in FIG. 8C of another embodiment of the present invention.

### DETAILED DESCRIPTION OF THE PREFERRED EMBODIMENTS

Some terms used in the detailed description are explained herein for illustrative clarity: 1) a through core via (TCV) means an electrically conductive via passing through the core and stopping at the upper and lower surfaces of the core; through silicon via (TSV), through glass via (TGV), through ceramic via (TCV) and through substrate via (TSV) have the similar meaning but for a specific core material; 2) a dark through core via (dTCV) means a through core via, but its location is not defined or unknown; 3) an effective through substrate via (eTSV) means an electrically conductive path having the similar ends at the upper and lower surfaces of the substrate core as a conventional through core via but having a different internal structure; 4) a pattern of through core vias mean a plurality of through core vias having a specific distribution for a specific application, where the distribution may be regular or irregular; 5) a micro-level method for producing through core vias means the method by using mechanical drilling, laser drilling or etching method to precisely form a pattern of holes first, and then the holes are filled with conductive material, where the feature of the micro-level method is that each hole including its size and location is precisely produced, for example, the holes are drilled one by one by mechanical or laser driller; 6) a macro-level method for producing through core vias means that a dielectric material column with metal wires (the metal wires are distributed in the column and aligned along the direction of the column) is first formed, and then the column is sliced into a plurality of pieces so as to form a plurality of substrate core units with a plurality of through core vias, where the feature of the micro-level method is that the through core vias are not produced through precisely positioned holes but through the metal wires in a dielectric material column; 7) a substrate core unit means one of the plurality of units included in a panel of substrate core; 8) a regional metal piece means a portion of a metal layer; 9) a pair of regional metal pieces means two regional metal pieces have the same size and shape on the upper and lower surfaces and align from the upper to lower surfaces of a substrate core unit; 10) a pair of openings means two openings with one in the upper dielectric layer and the other in the lower dielectric layer on the upper and lower surfaces of a substrate core unit for defining the location of an eTSV. These terms are further explained by referring to the drawings when describing the preferred embodiments of the present invention.

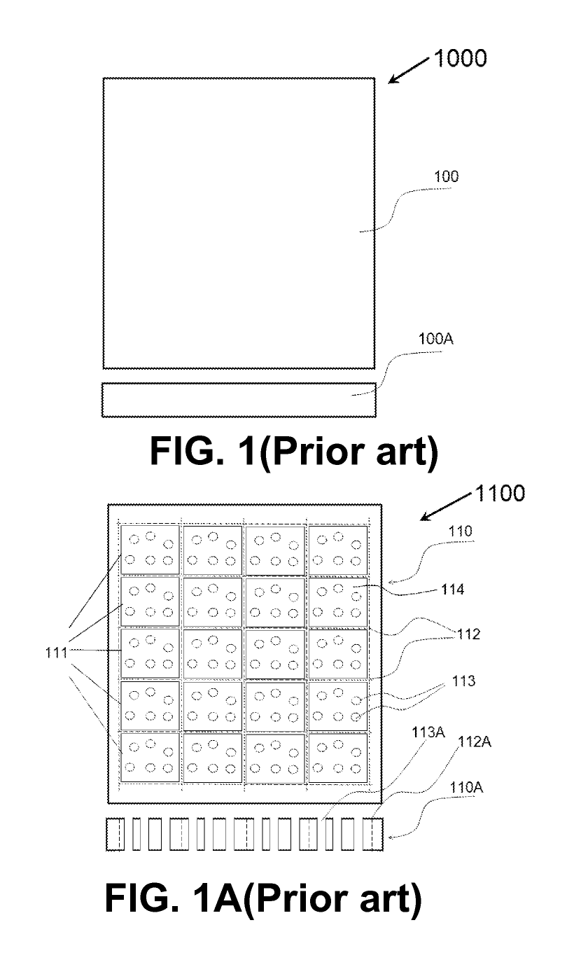

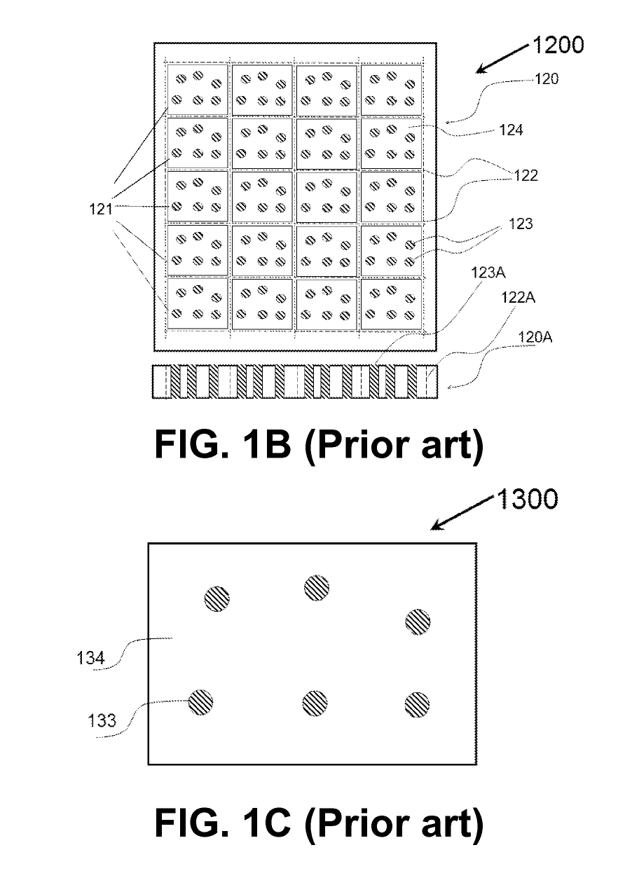

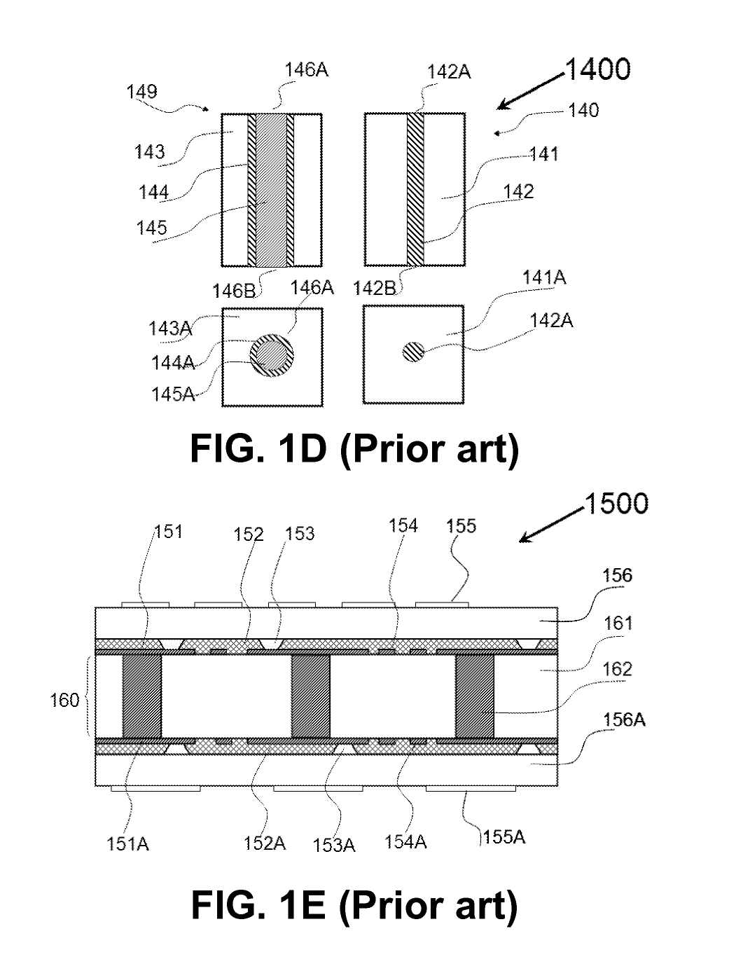

FIG. 1-1E are schematic diagrams for illustrating the basic features for producing an IC package substrate, including a homogeneous panel of substrate core, a pattern of through core vias, the structure of a through core via, and the usage of the through core vias when making an IC package substrate of prior arts. FIG. 1 illustrates a homogeneous panel of substrate core 1000 with the top view 100 and side view 100A separately showing the surface and the thickness of the homogeneous panel. Referring to FIG. 1A, the numerical symbol 1100 illustrates a panel with a plurality of holes formed in the homogeneous panel 1000 as illustrated in FIG. 1, where the numerical symbol 110 and 110A respectively designate the top view and the cross-sectional view of the panel 1100. In the top view 110 of the panel 1100, the numerical symbol 111 designates a plurality of substrate core units, the numerical symbol 112 designates the sawing streets along which the panel is divided into the plurality of substrate core units 111, and the numerical symbols 113 and 114 separately designate a pattern of holes and core material in each substrate core unit 111. In the cross-sectional view 110A of the panel 1100, the numerical symbol 113A designates the pattern of holes and the 112A designates the sawing streets among the plurality of substrate core units 111. It is noted that when drilling the pattern of holes 113 on the panel 1000, each hole of the pattern of holes 113 in each substrate core unit 111 is precisely positioned by referring to some global and local fiducial marks (not showed here for simplicity and clarity) made on the corners of the panel and the core units, and the coordinates of the locations of the holes are used by the following processing steps for coupling a plurality of metal pads with the through core vias. Referring to FIG. 1B, the numerical symbol 1200 illustrates a plurality of through core vias being formed by filling the holes 113 of the homogeneous panel 1100 as illustrated in FIG. 1A, where the numerical symbol 120 and 120A respectively designate the top view and the cross-sectional view of the panel 1200. In the top view 120 of the panel 1200, the numerical symbol 121 designates a plurality of substrate core units having a pattern of through core vias, the numerical symbol 122 designates the sawing streets along which the panel is divided into the plurality of substrate core units 121, and the numerical symbols 123 and 124 separately designate a pattern of through core vias and core material in each substrate core unit 121. In the cross-sectional view 120A of the panel 1200, the numerical symbol 123A designates the pattern of through core vias and the 112A designates the sawing streets among the plurality of substrate core units 121. Referring to FIG. 1C, the numerical symbol 1300 designates the top view of a substrate core unit with a pattern of through core vias, where the numerical symbols 133 and 134 separately designate the pattern of through core vias and the dielectric core material of the substrate core unit 1300. Referring to FIG. 1D, the numerical symbol 1400 designates the two typical structures of a through core via of prior arts; the numerical symbol 140 designates the structure of a through core via consisting of a solid metal via 142 embedded in dielectric core material 141, where the 142A and 142B designate the upper and lower ends of the solid metal via 142, and in the top view of the structure of a through core via 140, the 141A and 142A designate the dielectric core material and the solid metal via, and the numerical symbol 149 designates another structure of a through core via consisting of a metal cell 144 with a polymer core 145 embedded in dielectric core material 143, where the 146A and 146B designate the upper and lower ends of the through core via 144/145, and in the top view of the structure of the through core via 149, the 143A, 144A, 145A and 146A designate the dielectric core material, the metal cell, the polymer core, and the upper end of the through core via 144/145.

It is noted that the structure of through core via 149 illustrated in FIG. 1D is also called PTH (plated through hole), which is usually adopted in the organic core of an organic substrate and typically has a big size (about 100 um to 250 um in diameter, depending on the core thickness); and the structure of through core via 140 is adopted in silicon TSV interposer or glass TGV interposer, which typically has a small size (about 10 um to 50 um in diameter, depending on the core thickness). It is emphasized that the basic requirement for a through core via is to electrically connect a location on the upper surface of the substrate core (like the upper end 142A) to another location on the lower surface of the substrate core (like the lower end 142B), and the internal structure between the upper and lower ends is in fact not mandatory. It will be illustrated below that the inventive concept, i.e., the effective through core via of the present invention just meets the basic requirement for a through core via while having a different internal structure from the conventional structure of through core via.

FIG. 1E is a schematic diagram for illustrating an IC package substrate 1500 based on the conventional substrate core with through core vias of prior arts, which comprises the conventional substrate core 160 consisting of the core material 161 and through core vias 162, the first metal layer on the upper surface of the substrate core 160 consisting of the metal pads 151 and the circuits 154, the first metal layer on the lower surface of the substrate core 160 consisting of the metal pads 151A and the circuits 154A, the first dielectric layer 152 with embedded micro vias 153 on the upper surface of the substrate core 160, the first dielectric layer 152A with embedded micro vias 153A on the lower surface of the substrate core 160, one or more metal and dielectric layers 156 stacked over the first dielectric layer 152 on the upper surface of the substrate core 160, one or more metal and dielectric layers 156A stacked over the first dielectric layer 152A on the lower surface of the substrate core 160, and the terminal layers 155 and 155A on the top and bottom of the IC package substrate 1500. It is noted that when forming the first metal layer 151/154 or 151A/154A above or below the substrate core 160 with through core vias 162, the locations of the through core vias 162 need to be precisely defined in advance so that the metal pads 151 or 151A may capture the through core vias 162. In other words, the metal pads 151 or 151A are formed according to the precise locations of the through core vias 162 in the processing step for forming the first metal layer above or below the substrate core 160 with through core vias 162.

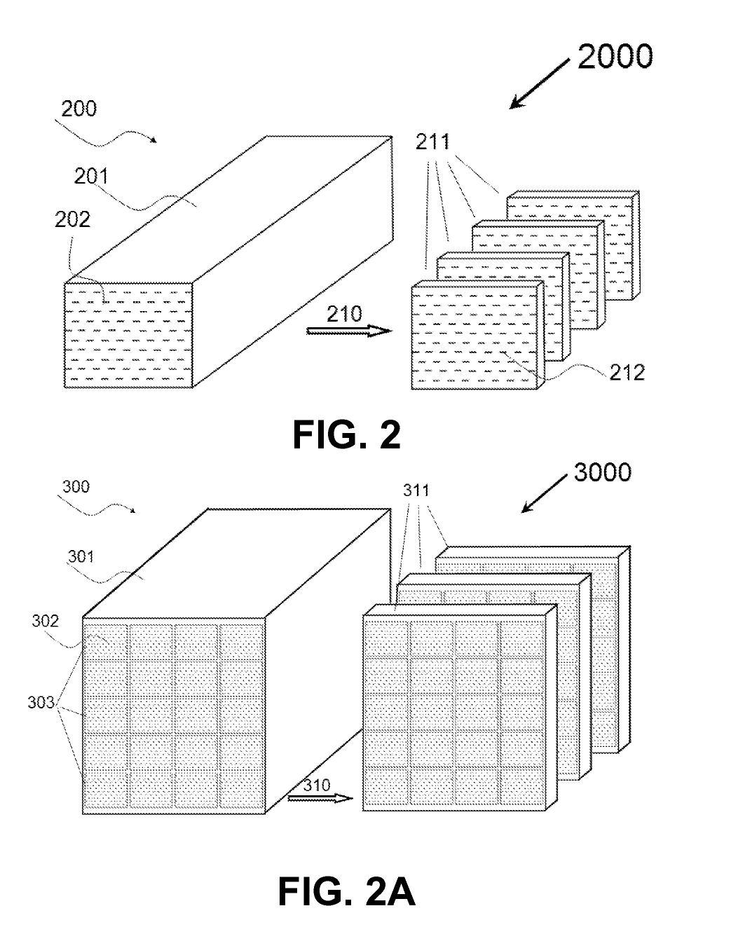

FIGS. 2 and 2A are schematic diagrams for illustrating a panel of inhomogeneous core layer based on a dielectric material column with metal wires. Referring to FIG. 2, the numerical symbol 2000 illustrates a dielectric material column 200 and a plurality of dielectric core units 211, wherein the dielectric material column consists of a plurality of embedded metal wires 202 in the matrix of dielectric material 201, the plurality of embedded metal wires 202 align in the longitudinal direction of the dielectric material columns 200, the numerical symbol 210 illustrates that the dielectric material column 200 may be sliced into plurality of substrate core units 211, each having a plurality of through core vias 212. Referring to FIG. 2A, the numerical symbol 3000 illustrates an ingot of dielectric material columns 300 and a plurality of panels of inhomogeneous core layers 311, the ingot of the dielectric material columns 300 is formed by integrating a plurality of dielectric material columns 303 where a matrix material 301 is used to encase and connect the plurality of dielectric material columns 303 with metal wires 302 from their sides. The numerical symbol 310 illustrates slicing the ingot of dielectric material columns 300 along the direction perpendicular to the embedded metal wires into a plurality of pieces so as to form a plurality of panels of inhomogeneous core layers 311, each including a plurality of dielectric core units connected together from their sides through the matrix material, each dielectric core unit including a plurality of through core vias. It is noted that the panel of inhomogeneous core layers 311 may also be produced by integrating a plurality of dielectric core units 212 through a panel of matrix material.

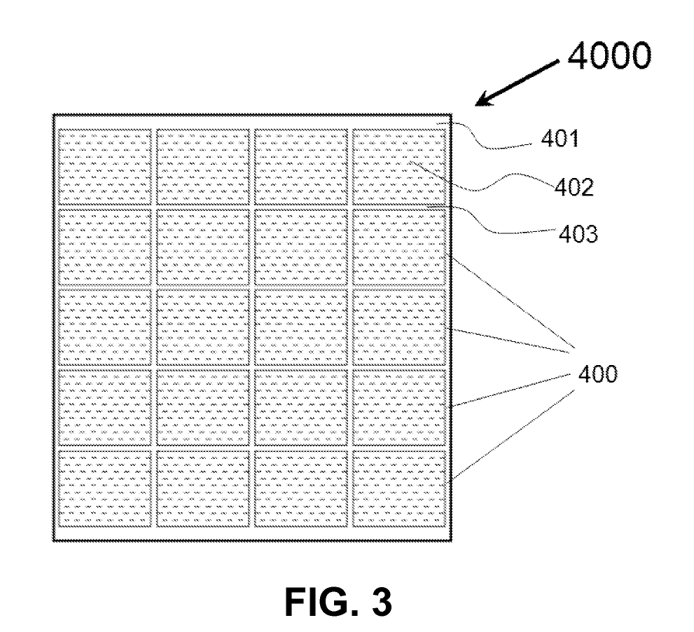

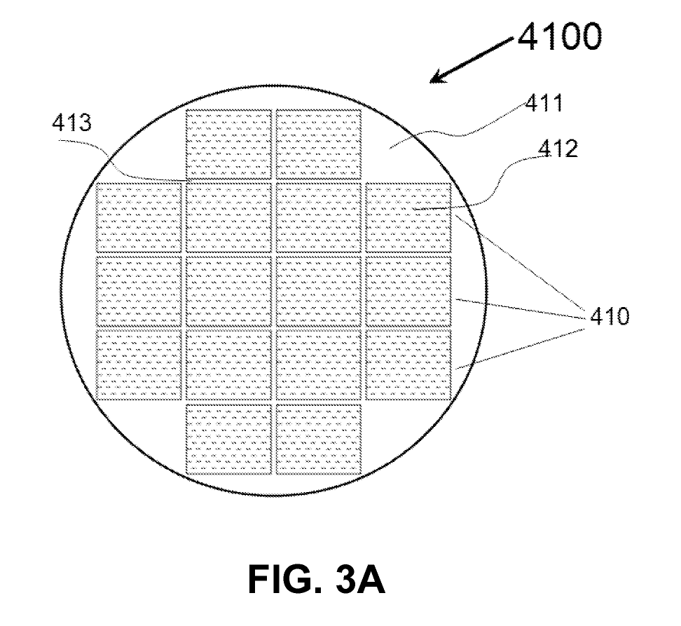

FIG. 3 is a schematic diagram for illustrating a rectangular panel of inhomogeneous core layer 4000 with a plurality of core units 400 embedded in a panel of matrix material 401, where the numerical symbol 402 illustrates a plurality of through core vias in each core unit 400, and the numerical symbol 403 illustrates the sawing streets in the matrix material 401 among the plurality of core units 400 for dividing the panel 4000 into a plurality of units 400. And FIG. 3A is a schematic diagram for illustrating a circular panel of inhomogeneous core layer 4100 with a plurality of core units 410 embedded in a panel of matrix material 411, where the numerical symbol 412 illustrates a plurality of through core vias in each core unit 410, and the numerical symbol 413 illustrates the matrix material among the plurality of core units 410 which is also used as the sawing streets for dividing the panel 4100 into a plurality of units 410. It is noted that a rectangular panel of inhomogeneous core layer is preferred for producing IC package substrate using the substrate processing platform, while a circular panel of inhomogeneous core layer is preferred for producing TSV interposers using the silicon wafer processing platform.

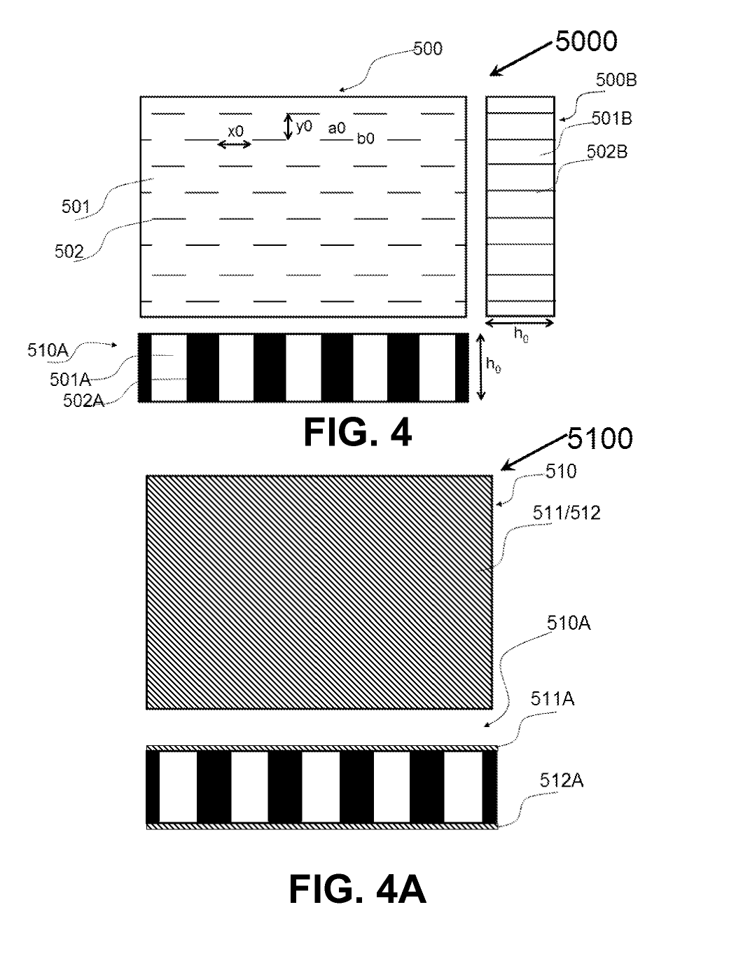

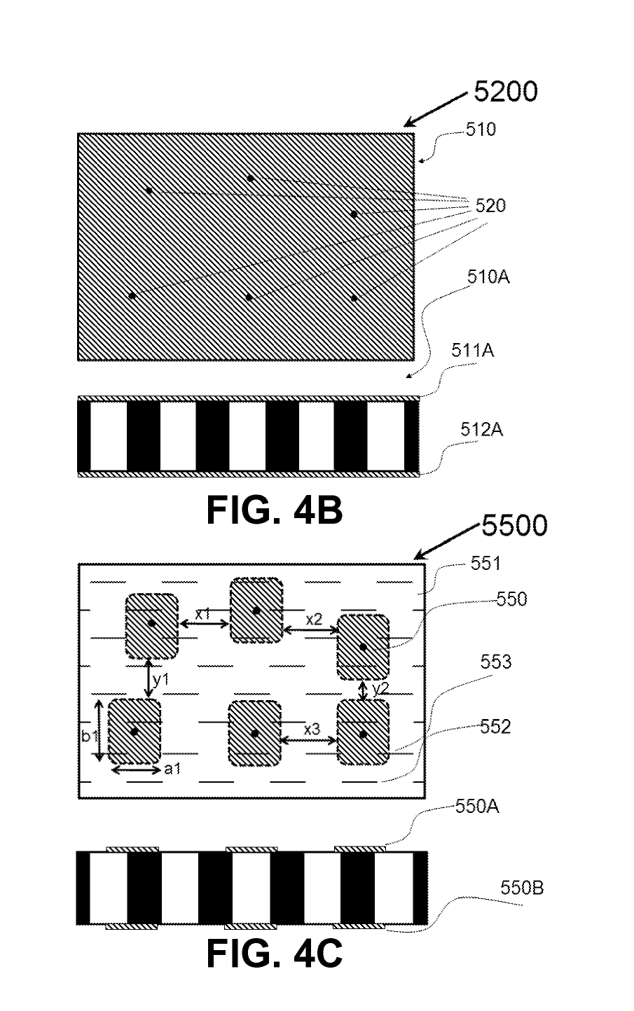

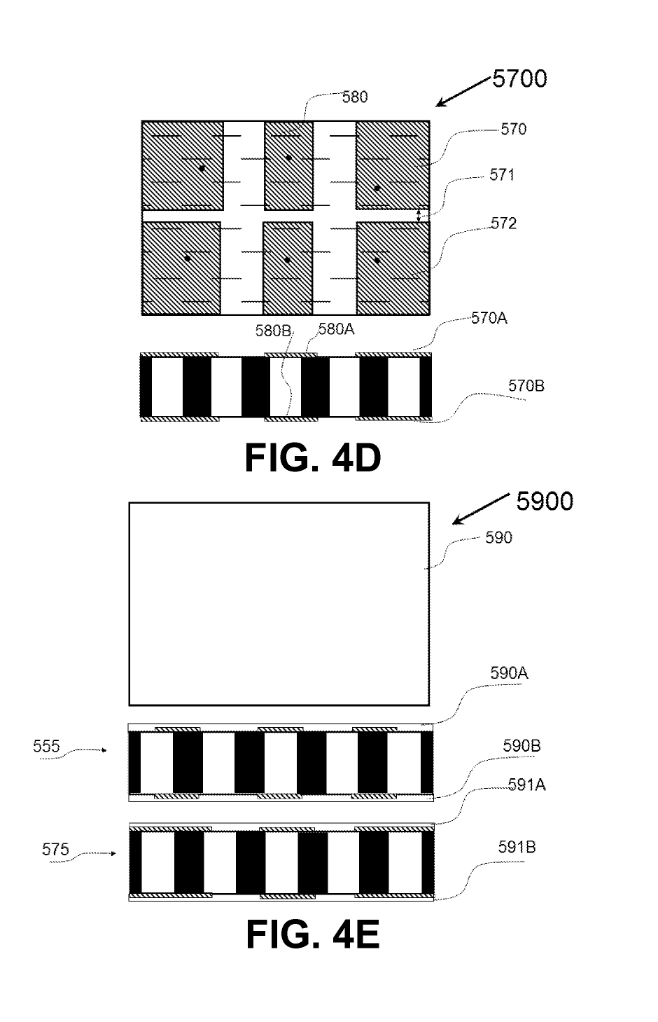

FIG. 4 is a schematic diagram for illustrating the structure of a dielectric core unit 5000 included in a panel of inhomogeneous core layer 4000 or 4100 as illustrated in previous FIG. 3 or 3A. In the top view 500 of the dielectric core unit 5000, the numerical symbols 501 and 502 designate the dielectric material and the through core vias, x0 and y0 designate the spaces among the through core vias 502 in X and Y directions, and a0 and b0 designate the length and thickness of a through core via. The numerical symbol 510A designates a cross-sectional view of the core unit 5000 along X direction and at a row of through core vias, where the numerical symbol 501A and 502A designate the dielectric material and the through core via, and h0 shows the thickness of the core unit 5000. The numerical symbol 510B designates a cross-sectional view of the core unit 5000 along Y direction, where the numerical symbol 501B and 502B designate the dielectric material and the through core via, and h0 shows the thickness of the core unit 5000. The core unit 500 with the line-type shape of through core vias 502 may be formed by slicing a column with a plurality of printed metal wires, where the column may be formed by printing metal lines on a ceramic green tape along one direction, stacking a plurality of ceramic green tapes into a column, and co-firing the column.

It is noted that a regular distribution of through core vias such as the diamond distribution of through core vias 502 as illustrated in FIG. 4 may be achieved by using the macro-level method, i.e., the method through a dielectric material column with metal wires. However, it is difficult to make an irregular distribution of through core vias by using the macro-level method. Furthermore, even for the regular distribution of through core vias prepared by the macro-level method, it is still a challenge to precisely control the locations of all the through core visa because the dimension of the dielectric material column with metal wires may shrink a lot during its solidification, causing the movement and deformation of the plurality of metal wires. So, the locations of all the through core vias distributed in each core unit of a panel of core layer as illustrated in FIGS. 3 and 3A are not required to be precisely defined in the present invention, but the via spaces x0 and y0 and via size a0 and b0 as illustrated in FIG. 4 are roughly defined. For example, the via spaces x0 and y0 are 60 um with 10% error, and the via size a0 and b0 are 60 um and 5 um with 10% error. The through core vias that their locations are not defined and their sizes and the spaces among them are roughly defined are named dark through core vias (dTCV) herein.

FIG. 4A is a schematic diagram for illustrating that two metal layers are stacked over each surface of the panel of inhomogeneous core layer illustrated in previous FIG. 3 or 3A, where the numerical symbol 5100 designates a dielectric core unit of the panel with two metal layers stacked over its upper and lower surfaces. The numerical symbol 511/512 designates the two metal layers on the surfaces of the dielectric core unit in its top view 510, and the numerical symbol 511A/512A designates the two metal layers on the surfaces of the dielectric core unit in its cross-sectional view 510A. FIG. 4B is a schematic diagram 5200 for illustrating a pattern of locations 520 at the surface of the dielectric core unit as illustrated in the previous FIG. 4A, where a pattern of effective through substrate vias are desired.

Referring to FIG. 4C, a schematic diagram 5500 for illustrating a number of regional metal pieces 550 from the top view, and 550A and 551A from the cross-sectional view, where the numerical symbol 551 designates the dielectric matrix material of the dielectric core unit, the numerical symbol 552 designates the dark through core vias connecting with the number of regional metal pieces 550, the numerical symbol 553 designates the dark through core vias not connecting with the number of regional metal pieces 550; the x1, x2 and x3 designates the spaces among the regional metal pieces 550 in X direction, and the y1 and y2 designates the spaces among the regional metal pieces 550 in Y direction. It is noted that the number of regional metal pieces 550 are formed by removing some portions of the two metal layers 511 and 512 illustrated in previous FIG. 4A according to the pattern of locations 520 illustrated in previous FIG. 4B, wherein the regional metal pieces on the upper surface and the regional metal pieces on the lower surface align with each other, forming a desired number of pairs of regional metal pieces, each pair of regional metal pieces have the same size and shape, align with each other from upper and lower surfaces of each dielectric core unit (a pair of regional metal pieces 550A and 550B, for example), the size of each pair of regional metal pieces is bigger than the space among the dTCV embedded and distributed in each dielectric core unit (that is, a1 in FIG. 4C is bigger than x0 in FIG. 4, b1 in FIG. 4C is bigger than y0 in FIG. 4C) so that each pair of regional metal pieces are electrically connected by at least one dTCV, the space between any two neighboring regional metal pieces on the same surface is bigger than the size of each dTCV (that is, x1, x3, x3 and all spaces in X direction in FIG. 4C is bigger than a0 in FIG. 4, y1, y2 and all spaces in Y direction in FIG. 4C is bigger than a0 in FIG. 4C) so that any two neighboring regional metal pieces are not electrically connected by the same dTCV, the location of each pair of regional metal pieces is defined according to the pattern of locations 520 illustrated in FIG. 4B so that the pairs of regional metal pieces encase the locations where a pattern of eTSV are desired. It is noted that only a portion of dark through core vias as may be captured for connecting with the pairs of regional metal pieces 550, and the remaining portion of the dark through core vias designated by the numerical symbol 553 are not connecting with the number of regional metal pieces 550, that is, the dark through core vias 553 are dummy.

Referring to FIG. 4D, a schematic diagram 5700 for illustrating another option for making the regional metal pieces surrounding the pattern of locations, where each regional metal piece may be made as big as possible provided that the neighboring regional metal pieces are electrically isolated from each other. It is noted that when using the line-type of dark through core vias, the space 571 in Y direction between the two neighboring regional metal pieces such as the two regional metal pieces 570 and 573 may be very small, and it is also noted that the regional metal pieces on the same surface may be different in size, such as the bigger one 570 and the smaller one 580, the metal pieces 570 and 580 in top view correspond to the pairs of metal pieces 570A/570B and 580A/580B in cross-sectional view. It will be illustrated in the following that a bigger regional metal piece may be more flexible for defining the size and location of an effective through core via.

FIG. 4E is a schematic diagram for illustrating that two dielectric layers are further stacked over each surface of the panel of inhomogeneous core layer illustrated in the previous FIG. 3 or 3A, covering the two metal layers of regional metal pieces 550 or 570 illustrated in the previous FIG. 4C or 4D, the numerical symbol 5900 designates a dielectric core unit of the panel with two metal layers and two dielectric layers stacked over its upper and lower surfaces, where the numerical symbol 590 designates the dielectric layer from the top view, the numerical symbol 555 and 575 designate the cross-sectional view of a dielectric core unit with the metal and dielectric layers on its upper and lower surfaces, where the dielectric layers 590A and 590B cover the regional metal pieces such as 550A and 550B illustrated in FIG. 4C, and the dielectric layers 591A and 591B cover the regional metal pieces such as 570A and 570B illustrated in FIG. 4D.

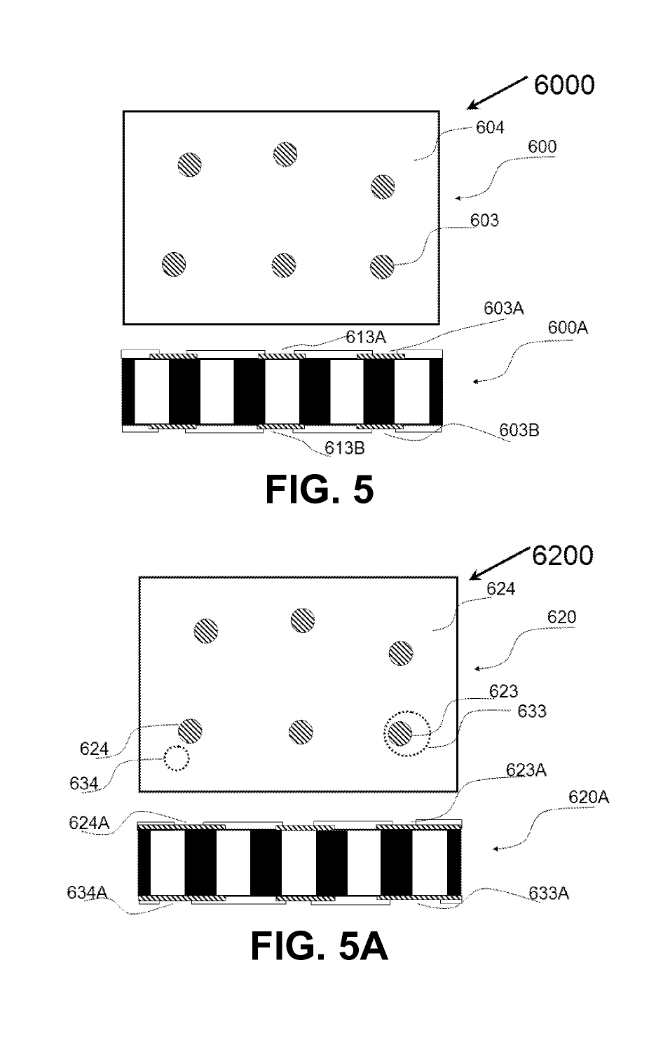

FIG. 5 is a schematic diagram for illustrating a representative substrate core unit 6000 having a pattern of eTSV of a panel of substrate core, where the numerical symbol 600 designates the top view of the substrate core unit 6000 having a pattern of eTSV 603 exposed in the openings of the dielectric core layer 604, the pattern of eTCV 603 is precisely defined by forming a pattern of openings based on a micro-level method in each dielectric layer 590 on upper and lower surfaces illustrated in the previous FIG. 4E, wherein the locations of the pattern of openings are determined according to the desired locations where effective through core vias are expected; each pair of exposed metals in each pair of openings form the two ends of an effective through via (eTSV). It is noted that from the top view, the pattern of effective through core vias 603 according to one embodiment of the present invention may have the similar outline as the conventional through core vias 133 as illustrated in the previous FIG. 1C of prior arts. However, the internal structure of the pattern of effective through core vias 603 as illustrated in the cross-section view 600A of the substrate core unit 6000 is different from the conventional structure of a through core via 1400 as illustrated in the previous FIG. 1D. The internal structure of an effective through core via consists of a pair of regional metal pieces connected by at least one dark through core via with undefined locations.

FIG. 5A is a schematic diagram for illustrating a representative substrate core unit 6200 having a pattern of eTSV where the regional metal pieces are made as big as possible. In the top view 620 of the substrate core unit 6200, the numerical symbols 623 and 633 designate the upper and lower ends of one effective through core via, and the numerical symbols 624 and 634 designate the upper and lower ends of another effective through core via. Correspondingly, in the cross-sectional view 620A of the substrate core unit 6200, the numerical symbols 623A and 633A designates the upper end and lower ends of one effective through core vias, and the numerical symbols 624A and 634A designates the upper end and lower ends of another effective through core vias. It is seen that when the regional metal pieces are taken as big as possible, the sizes of the upper and lower ends of an effective through core via may be different, and the locations of the upper and lower ends of an effective through core via may not align from the upper to lower surfaces, showing the flexibility for designing effective through core vias for a specific application.

It is noted that the key inventive concepts in the substrate core 6000 or 6200 illustrated in FIGS. 5 and 5A according to the embodiments of the present invention include 1) the dark through core vias (which may be produced by a macro-level method with a low cost) are adopted, and only a portion of all the dark through core vias may be active, and the remaining portion of all the dark through core vias are dummy, 2) a number of pairs of regional metal pieces are adopted for activating a portion of all the dark through core vias for forming the effective through core vias, 3) two dielectric layers with a desired pattern of openings (the openings in the dielectric layers may be produced by a micro-level method with a low cost) are adopted for defining the locations and sizes of the two ends of each effective through core via.

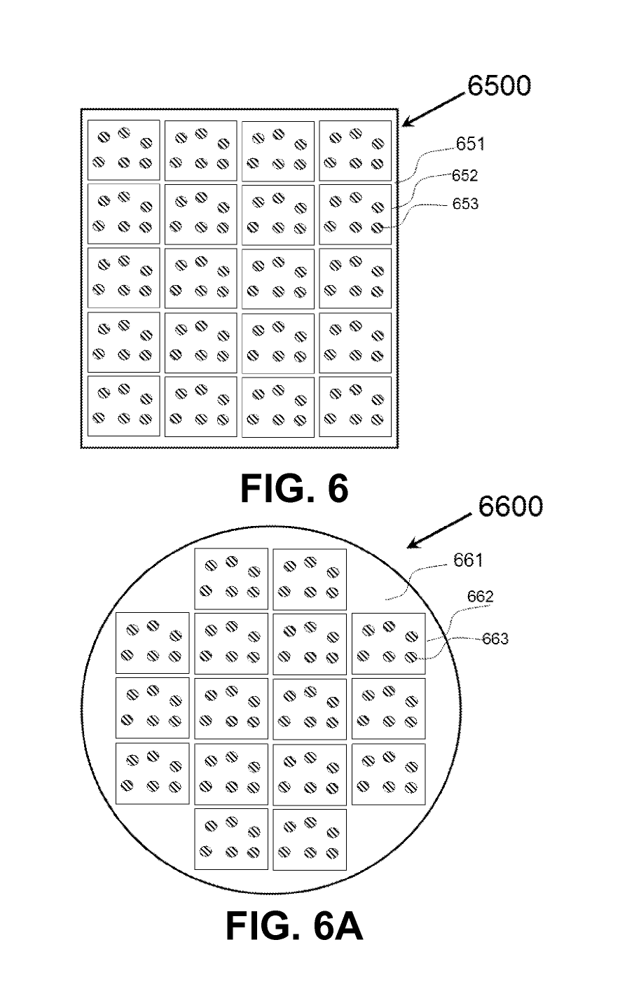

FIG. 6 is a schematic diagram for illustrating a rectangular panel of substrate core 6500 including a plurality of substrate core units 652 connected by the panel of matrix material 611, each substrate core unit having a pattern of eTSV 633. And FIG. 6A is a schematic diagram for illustrating a circular panel of substrate core 6600 including a plurality of substrate core units 662 connected by the panel of matrix material 661, each substrate core unit having a pattern of eTSV 663. It is noted that the rectangular panel of substrate core 6500 is preferred by a substrate manufacturing platform, while the circular panel of substrate core 6600 is preferred by a silicon wafer manufacturing platform.

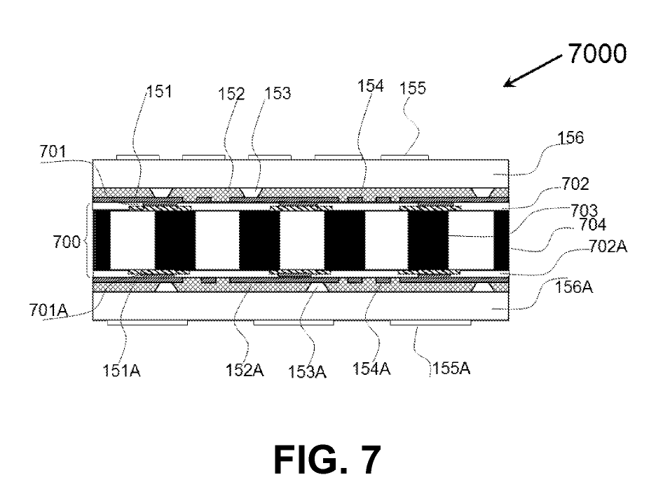

FIG. 7 is a schematic diagram for illustrating an IC package substrate 7000 having a substrate core unit with a pattern of eTSV of one embodiment of the present invention. Referring to the conventional IC package substrate 1500 of prior arts as illustrated in FIG. 1E, the substrate core 700 of IC package substrate 7000 is different from the substrate core 160 of the convention IC package substrate 1500. The inventive concepts in the substrate core 700 include 1) the dark through core vias (which may be produced by a macro-level method with a low cost) are adopted, wherein only a portion of all the dark through core vias may be active (such as the through core vias designated by the numerical symbol 703), and the remaining portion of all the dark through core vias are dummy (such as the through core vias designated by the numerical symbol 704), 2) a number of pairs of regional metal pieces are adopted for activating a portion of all the dark through core vias for forming the effective through core vias, 3) two dielectric layers 702 and 702A with a desired pattern of openings (the openings in the thin dielectric layers may be produced by a micro-level method with a low cost) are adopted for defining the locations and sizes of the two ends 701 and 701A of each effective through core via, and the other numerical symbols 151/151A, 152/152A, 153//153A, 154/154A, 155/155A, and 156/156A in the IC package substrate 7000 designate the same items as those of the conventional IC package substrate 1500 illustrated in FIG. 1E.

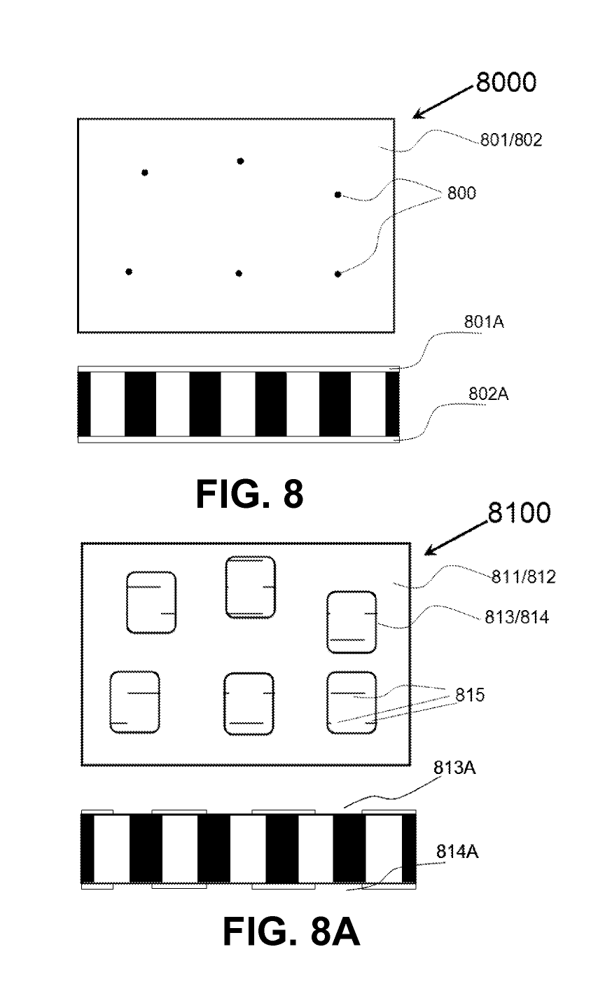

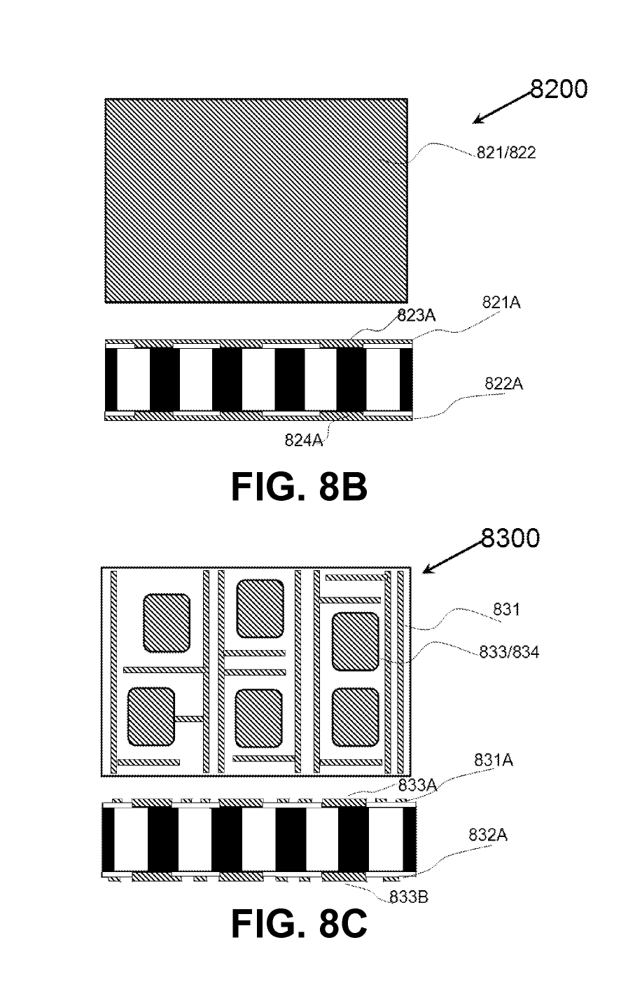

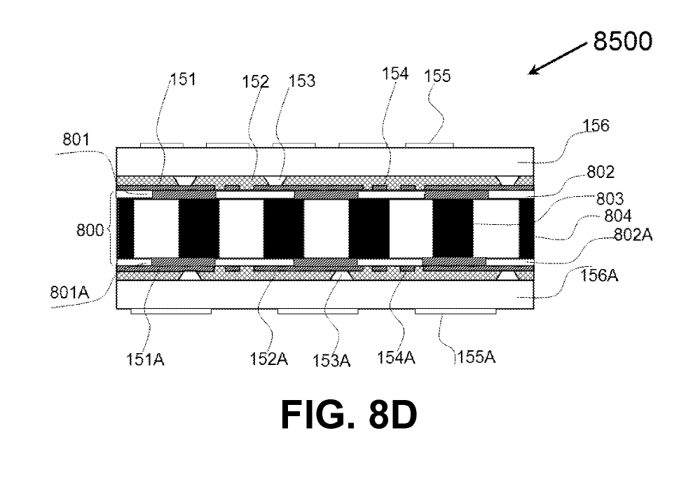

FIG. 8 to FIG. 8D are schematic diagrams for illustrating a substrate core unit with effective through core vias of another preferred embodiment of the present invention. Referring to FIG. 8, the numerical symbol 8000 illustrates two dielectric layers 801/802 in the top view or 801A/802A in the cross-sectional view are stacked over each surface of the dielectric core unit 5000 as illustrated in the previous FIG. 4, and the numerical symbol 800 designates a pattern of locations where a pattern of eTSV are desired.

Referring to FIG. 8A, the numerical symbol 8100 illustrates that a pattern of openings 813/814 in the top view or 813A/814A in the cross-sectional view are formed in the two dielectric layers 811 and 812 according to the pattern of locations 800 illustrated in FIG. 8, wherein the openings in the upper dielectric layer and the openings in the lower dielectric layer form a desired number of pairs of openings such as 813A and 814A, each pair of openings are the same in size and shape, align from the upper to lower surfaces of the dielectric core unit, and locate at the desired position, each opening is bigger than the space among the dark through core vias so that at least one dark through core via designated by the numerical symbol 815 are captured in each opening, and the space between any two neighboring openings on the same surface is bigger than the size of each dark through core via so that any two neighboring openings on the same surface are not connected by the same dark through core via.

Referring to FIG. 8B, the numerical symbol 8200 illustrates two metal layers 821/822 in the top view or 821A/822A in the cross-sectional view are stacked over the two dialectic layers 811/812 with the openings 813/814 or 813A/814A illustrated in the previous FIG. 8A, wherein the numerical symbols 823A/824A designate the two ends of each effective through core via, which is formed by the portions of the two metal layers 821/822 or 821A/822A filled in the pairs of openings 813A and 814A as illustrated in FIG. 8A.

Referring to FIG. 8C, the numerical symbol 8300 illustrates the two metal layers 821/822 illustrated in FIG. 8B may be further processed as a pattern of metal layers including the pattern of eTSV consisting of the metals in the openings of the dielectric layers and a number of circuits consisting of the metals outside the openings of the dielectric layers, such as the circuits 831 in the top view or 831A and 832A in the cross-sectional view and the effective through core vias 833/834 in the top view or 833A and 833B in the cross-sectional view.

Referring to the substrate core unit illustrated in FIGS. 5 and 5A and the substrate core unit illustrated in FIG. 8C, the former is produced by stacking the two metal layers first, while the latter is produced by stack the two dielectric layers first. The advantage of the former is that the effective through core vias may be more flexible, while the advantage of the latter is that the two metal layers may also be used as circuit layer besides the effective through core vias.

FIG. 8D is a schematic diagram for illustrating an IC package substrate 8500 having the substrate core unit 8300 with a pattern of eTSV 833A and 833B as illustrated in FIG. 8C of another preferred embodiment of the present invention. Referring to the conventional IC package substrate 1500 of prior arts illustrated in FIG. 1E, the substrate core 800 of the IC package substrate 8500 is different from the substrate core 160 of the convention IC package substrate 1500. The inventive concepts in the substrate core 800 include 1) the dark through core vias (which may be produced by a macro-level method with a low cost) are adopted, wherein only a portion of all the dark through core vias may be active (such as the through core vias designated by the numerical symbol 803), and the remaining portion of all the dark through core vias are dummy (such as the through core vias designated by the numerical symbol 804), 2) two dielectric layers 802 and 802A with a desired pattern of openings (the openings in the dielectric layers may be produced by a micro-level method with a low cost) are adopted for defining the locations and sizes of the two ends 801 and 801A of each effective through core via. 3) two metal layers are adopted for forming the upper and lower ends 801 and 801A of each effective through core via.

Referring to FIGS. 2 to 6A, a method for making a panel of substrate core with effective through substrate vias according to one preferred embodiment of the present invention, comprising the following key steps:
a) providing a plurality of dielectric material columns, wherein each dielectric material column includes a plurality of embedded metal wires, the plurality of embedded metal wires align in the longitudinal direction of the dielectric material columns and the locations of the embedded metal wires may be dark;
b) integrating the plurality of dielectric material columns into an ingot of dielectric material columns by using a matrix material to encase and connect together the plurality of dielectric material columns from their sides;
c) slicing the ingot of dielectric material columns along the direction perpendicular to the embedded metal wires into a plurality of pieces so as to form a plurality of inhomogeneous core layers with each including a plurality of dielectric core units connected together from sides through the matrix material, each dielectric core unit including a plurality of dark through core vias (dTCV), wherein the locations of the plurality of dTCV may be dark;
d) stacking two metal layers with each on one surface of the inhomogeneous core layer;
e) removing some portions of each layer of the two metal layers to form a desired number of regional metal pieces on each region corresponding to each dielectric core unit; wherein the regional metal pieces on the upper surface and the regional metal pieces on the lower surface align with each other, forming a desired number of pairs of regional metal pieces, each pair of regional metal pieces have the same size and shape, align with each other from upper and lower surfaces of each dielectric core unit, the size of each pair of regional metal pieces is bigger than the space among the dTCV embedded and distributed in each dielectric core unit so that each pair of regional metal pieces are electrically connected by at least one dTCV, the space between any two neighboring regional metal pieces on the same surface is bigger than the size of each dTCV so that any two neighboring regional metal pieces are not electrically connected by the same dTCV, the location of each pair of regional metal pieces is defined according to the location of each desired eTSV so that each pair of regional metal pieces encase the location of each desired eTSV;
f) stacking two dielectric layers with each on one surface of the inhomogeneous core layer, covering all the regional metal pieces;
g) forming a pattern of openings in each region of each dielectric layer corresponding to each dielectric core unit so as to expose a portion of each regional metal piece, each pair of exposed metals in each pair of regional metal pieces form an effective through via (eTSV) at the desired location, forming an electrically conductive path from the upper to lower surfaces of the substrate core, resulting in a panel of substrate core having a plurality of substrate core units and each substrate core unit having a desired pattern of eTSV.

Referring to FIGS. 8 to 8D, a method for making a panel of substrate core with effective through substrate vias according to another preferred embodiment of the present invention, comprising the following key steps:
a) providing a plurality of dielectric material columns, wherein each dielectric material column includes a plurality of embedded metal wires, the plurality of embedded metal wires align in the longitudinal direction of the dielectric material columns and the locations of the embedded metal wires may be dark;
b) integrating the plurality of dielectric material columns into an ingot of dielectric material columns by using a matrix material to encase and connect together the plurality of dielectric material columns from their sides;
c) slicing the ingot of dielectric material columns along the direction perpendicular to the embedded metal wires into a plurality of pieces so as to form a plurality of inhomogeneous core layers with each including a plurality of dielectric core units connected together from sides through the matrix material, each dielectric core unit including a plurality of dark through core vias (dTCV), wherein the locations of the plurality of dTCV may be dark;
d) forming two dielectric layers with each on one surface of the inhomogeneous core layer;
e) forming a desired number of openings in each region of each dielectric layer corresponding to each dielectric core unit, the openings in each region of the upper dielectric layer and the openings in each region of the lower dielectric layer form a number of pairs of openings, each pair of openings are the same in size and shape, align from the upper to lower surfaces of each dielectric core unit, and locate at the desired position for forming a desired eTSV in the following processing step; the size of each pair of openings is bigger than the space among the dTCV embedded in the dielectric core unit so that there is at least one dTCV between each pair of openings, the space between any two neighboring openings on the same surface is bigger than the size of each dTCV so that any two neighboring openings on the same surface are not connected by the same dTCV;
f) stacking two metal layers with each on one surface of the inhomogeneous core layer, covering the two dielectric layers and filling the openings in the two dielectric layers, wherein the portions of the metal layers filled inside the openings of the two dielectric layers form the desired pattern of eTSV in each region corresponding to each dielectric core unit, resulting in a panel of substrate core having a plurality of substrate core units and each substrate core unit having a desired pattern of eTSV.

Referring to FIGS. 2 to 8D, a panel of substrate core with effective through substrate vias according to one preferred embodiment of the present invention, comprising:
an inhomogeneous core layer consisting of a plurality of dielectric core units and a panel of matrix material, wherein each dielectric core unit is a piece of square or rectangular dielectric material having two surfaces and four sides, the plurality of dielectric core units are embedded in the panel of matrix material with the two surfaces of each dielectric core unit exposed in the two surfaces of the inhomogeneous core layer, and the shape of the panel of substrate core is defined by the shape of the panel of matrix material;
a plurality of dark through core via (dTCV) embedded and distributed in each of the dielectric core unit, wherein each dTCV is an electrically conductive via passing through the dielectric core unit from its upper to lower surfaces, and the locations of the dTCV may be dark; and
a pattern of effective through substrate via (eTSV) in each region corresponding to each dielectric core unit, forming a desired pattern of electrically conductive paths from the upper to lower surfaces of the substrate core corresponding to each region of each dielectric core unit, wherein the pattern of eTSV are formed through a portion of the plurality of dTCV, two metal layers and two dielectric layers having a pattern of openings in each layer.

Referring to FIGS. 2 to 8D, a substrate core unit with a pattern of effective through substrate vias according to one preferred embodiment of the present invention, comprising:
a dielectric core layer having an upper surface and a lower surface;
a plurality of dark through core vias (dTCV) embedded and distributed in the dielectric core layer, wherein each dTCV is an electrically conductive via passing through the dielectric core layer from its upper to lower surfaces, and the locations of the plurality of dTCV may not be defined; and
a pattern of effective through substrate vias (eTSV), wherein the pattern of eTSV form a desired pattern of electrically conductive paths from the upper to lower surfaces of the substrate core unit, and the pattern of eTSV are formed through a portion of the plurality of dTCV, two metal layers and two dielectric layers with each having a pattern of openings.

It is noted that the line-type shape of dark through core vias are taken for describing the embodiments of the present invention. However, the geometric shape of the dark through core vias according to the present invention is not limited to the line-type shape; it may include other shapes, like circular or square shapes of dark through core vias. Furthermore, the material for the dielectric column may be selected according to the need in a specific application, which may be ceramic, glass or organic material. An application example of substrate core unit with effective through core vias that may be produced in a low cost according to the present invention is a ceramic substrate core unit with effective through core vias, wherein the thickness of the ceramic core layer is about 0.3 to 0.5 mm, the thickness of the two metal is about 1 um to 2 um, the thickness of the two dielectric layers is about 1 um, the size of the two ends of each effective through core via is about 10 um to 20 um, the pitch among the effective through core vias is about 100 um to 200 um, the distribution of the effective through core vias may be irregular. Because ceramic material has very good dielectric property and low CTE (coefficient of thermal expansion), such a ceramic substrate core may be preferred for producing a ceramic TCV interposer for 2.5D or 3D IC chip packaging.

It is also noted that the key idea in the present invention is to produce a pattern of effective through core vias by using a macro-micro hybrid method which is a combination of the macro-level method where a plurality of dark through core vias are produced through a dielectric column with metal wires and the micro-level method where a pattern of openings in a very thin dielectric layer are precisely produced by drilling or etching process. And the key inventive concepts in the substrate core according to the present invention include 1) the dark through core vias (which may be produced by a macro-level method with a low cost) are adopted, wherein only a portion of all the dark through core vias may be active, and the remaining portion of all the dark through core vias are dummy, 2) a desired number of pairs of regional metal pieces are adopted for activating a portion of all the dark through core vias for forming the effective through core vias, 3) two dielectric thin layers with a desired pattern of openings (the openings in the thin dielectric layers may be produced by a micro-level method with a low cost) are adopted for defining the locations and sizes of the two ends of each effective through core via.

Although the present invention is described in some details for illustrative purpose with reference to the embodiments and drawings, it is apparent that many other modifications and variations may be made without departing from the spirit and scope of the present invention.

1. A panel of substrate core with effective through substrate vias, comprising:
An inhomogeneous core layer consisting of a plurality of dielectric core units and a panel of matrix material, wherein the inhomogeneous core layer has an upper surface and a lower surface, each dielectric core unit is a piece of dielectric material, having an upper surface and a lower surface corresponding to the upper and lower surfaces of the inhomogeneous core layer, the plurality of dielectric core units are embedded in the panel of matrix material, and the upper and lower surfaces of each dielectric core unit are a portion of the upper and lower surfaces of the inhomogeneous core layer, respectively;
a plurality of dark through core vias (dTCV) embedded and distributed in each dielectric core unit, wherein each dTCV is an electrically conductive via passing through the dielectric core unit from its upper to lower surfaces;
two metal layers, wherein each metal layer includes a plurality of regional metal pieces, the plurality of regional metal pieces included in one metal layer are stacked on the upper surface of the inhomogeneous core layer, the plurality of regional metal pieces included in the other metal layer are stacked on the lower surface of the inhomogeneous core layer, the regional metal pieces align with each other from the upper to lower surfaces of the inhomogeneous core layer and form a plurality of pairs of regional metal pieces, and the two regional metal pieces in each pair of regional metal pieces are electrically connected by at least one dTCV;
two dielectric layers, wherein each dielectric layer includes a pattern of openings;
a pattern of effective through substrate vias (eTSV), wherein each eTSV is an electrically conductive path from one regional metal piece to the other regional metal piece corresponding to a pair of regional metal pieces, and the pattern of the eTSV is determined by the pattern of openings in the two dielectric layers; and
a feature of internal structure, wherein the plurality of dark through core vias (dTCV) are more in number than the pairs of regional metal pieces by multiple times, the location of any regional metal piece is pre-determined regardless of the location of any dTCV, and the plurality of pairs of regional metal pieces are electrically connected by the plurality of dTCV in a random way, wherein the number of the dTCV being connected with each pair of regional metal pieces is randomly determined and is diverse, and the connecting position at which a dTCV is electrically connected with each pair of regional metal pieces is randomly determined and is diverse.

2. The panel of substrate core of claim 1, wherein the two metal layers are respectively stacked on the upper and lower surfaces of the inhomogeneous core layer, the two dielectric layers are respectively stacked over the two metal layers, the pattern of openings in the two dielectric layers expose a portion of each regional metal piece included in the two metal layers, an effective through substrate via (eTSV) is formed from the exposed portion of one regional metal piece to the exposed portion of the other regional metal piece corresponding to each pair of regional metal pieces, and all the eTSV corresponding to all pairs of regional metal pieces form a pattern of eTSV.

3. The panel of substrate core of claim 1, wherein the two dielectric layers are respectively stacked on the upper and lower surfaces of the inhomogeneous core layer, correspondingly called upper and lower dielectric layers, the pattern of openings in the upper dielectric layer and the pattern of openings in the lower dielectric layer align with each other from the upper to lower surfaces of the inhomogeneous core layer, forming a pattern of pairs of openings, the two metal layers are respectively stacked over the two dielectric layers with the pattern of openings, covering and filling all the openings in the two dielectric layers, the metals in all the openings of the two dielectric layers form the regional metal pieces included in the two metal layers, a pair of regional metal pieces is formed corresponding to a pair of openings, an effective through substrate via (eTSV) is formed from one regional metal piece to the other regional metal piece corresponding to a pair of regional metal pieces, and all the eTSV corresponding to all pairs of regional metal pieces form a pattern of eTSV.

4. The panel of substrate core of claim 1, wherein the material for the dielectric core units of the inhomogeneous core layer is ceramic, glass or organic material.

5. The panel of substrate core of claim 1, wherein the shape of the panel of matrix material is circular or rectangular.

6. The panel of substrate core of claim 1, further comprising one or more circuit layers, one or more dielectric layers and one terminal layer stacked over the pattern of eTSV on one surface of the panel of substrate core, and at least one terminal layer stacked over the pattern of eTSV on the other surface of the panel of substrate core, forming a panel of IC chip package substrate.

7. A substrate core unit with a pattern of effective through substrate vias, comprising:
A dielectric core layer having an upper surface and a lower surface;
a plurality of dark through core vias (dTCV) embedded and distributed in the dielectric core layer, wherein each dTCV is an electrically conductive via passing through the dielectric core layer from its upper to lower surfaces;
two metal layers, wherein each metal layer includes a plurality of regional metal pieces, the plurality of regional metal pieces included in one metal layer are stacked on the upper surface of the dielectric core layer, the plurality of regional metal pieces included in the other metal layer are stacked on the lower surface of the dielectric core layer, the regional metal pieces align with each other from the upper to lower surfaces of the dielectric core layer and form a plurality of pairs of regional metal pieces, and the two regional metal pieces in each pair of regional metal pieces are electrically connected by at least one dTCV;
two dielectric layers, wherein each dielectric layer includes a pattern of openings;
a pattern of effective through substrate vias (eTSV), wherein each eTSV is an electrically conductive path from one regional metal piece to the other regional metal piece corresponding to a pair of regional metal pieces, and the pattern of the eTSV is determined by the pattern of openings in the two dielectric layers; and
a feature of internal structure, wherein the plurality of dark through core vias (dTCV) are more in number than the pairs of regional metal pieces by multiple times, the location of any regional metal piece is pre-determined regardless of the location of any dTCV, and the plurality of pairs of regional metal pieces are electrically connected by the plurality of dTCV in a random way, wherein the number of the dTCV being connected with each pair of regional metal pieces is randomly determined and is diverse, and the connecting position at which a dTCV is electrically connected with each pair of regional metal pieces is randomly determined and is diverse.

8. The substrate core unit of claim 7, wherein the two metal layers are respectively stacked on the upper and lower surfaces of the dielectric core layer, the two dielectric layers are respectively stacked over the two metal layers, the pattern of openings in the two dielectric layers expose a portion of each regional metal piece included in the two metal layers, an effective through substrate via (eTSV) is formed from the exposed portion of one regional metal piece to the exposed portion of the other regional metal piece corresponding to each pair of regional metal pieces, and all the eTSV corresponding to all pairs of regional metal pieces form a pattern of eTSV.

9. The substrate core unit of claim 7, wherein the two dielectric layers are respectively stacked on the upper and lower surfaces of the dielectric core layer, correspondingly called upper and lower dielectric layers, the pattern of openings in the upper dielectric layer and the pattern of openings in the lower dielectric layer align with each other from the upper to lower surfaces of the dielectric core layer, forming a pattern of pairs of openings, the two metal layers are respectively stacked over the two dielectric layers, covering and filling all the openings in the two dielectric layers, the metals in all the openings form the regional metal pieces included in the two metal layers, a pair of regional metal pieces is formed corresponding to a pair of openings, an effective through substrate via (eTSV) is formed from one regional metal piece to the other regional metal piece corresponding to a pair of regional metal pieces, and all the eTSV corresponding to all pairs of regional metal pieces form a pattern of eTSV.

10. The substrate core unit of claim 7, wherein the material for the dielectric core layer is ceramic, glass or organic material.

11. The substrate core unit of claim 7, further comprising one or more circuit layers, one or more dielectric layers and one terminal layer stacked over the pattern of eTSV on one surface of the substrate core unit, and at least one terminal layer stacked over the pattern of eTSV on the other surface of the substrate core unit, forming an IC chip package substrate unit.

12. A method for making a panel of substrate core with effective through substrate vias, comprising,
a) providing a plurality of dielectric material columns, wherein each dielectric material column includes a plurality of embedded metal wires, the plurality of embedded metal wires are distributed in the dielectric material columns, aligning in the longitudinal direction of the dielectric material columns, and the locations of the embedded metal wires may be not be defined;
b) integrating the plurality of dielectric material columns into an ingot of dielectric material columns by using a matrix material to encase and connect the plurality of dielectric material columns from their sides;
c) slicing the ingot of dielectric material columns along the direction perpendicular to the embedded metal wires into a plurality of pieces so as to form a plurality of inhomogeneous core layers with each including a plurality of dielectric core units connected together from sides by the matrix material, each dielectric core unit including a plurality of dark through core vias (dTCV) formed through the metal wires, wherein the locations of the plurality of dTCV may not be defined;
d) stacking two metal layers with each on one surface of the inhomogeneous core layer;
e) removing some portions of each layer of the two metal layers to form a desired number of regional metal pieces in the region of each dielectric core unit; wherein the regional metal pieces on the upper surface and the regional metal pieces on the lower surface of each dielectric core unit align with each other, forming a desired number of pairs of regional metal pieces, each pair of regional metal pieces have the same size and shape, align with each other from upper and lower surfaces of each dielectric core unit, the size of each pair of regional metal pieces is bigger than the space among the dTCV embedded and distributed in each dielectric core unit so that each pair of regional metal pieces are electrically connected by at least one dTCV, the space between any two neighboring regional metal pieces on the same surface is bigger than the size of each dTCV so that any two neighboring regional metal pieces are not electrically connected by the same dTCV, the location of each pair of regional metal pieces is determined according to the location of each desired eTSV;
f) stacking two dielectric layers with each on one surface of the inhomogeneous core layer, covering the two metal layers consisting of the desired number of regional metal pieces in the region of each dielectric core unit;
g) forming a pattern of openings in each region of the two dielectric layers corresponding to each dielectric core unit so as to expose a portion of each regional metal piece underneath the two dielectric layers, each pair of exposed metals in each pair of regional metal pieces form the two ends of an effective through via (eTSV) at the desired location, resulting in a panel of substrate core having a plurality of substrate core units, and each substrate core unit having a desired pattern of eTSV.

13. A method for making a panel of substrate core with effective through substrate vias, comprising,
a) providing a plurality of dielectric material columns, wherein each dielectric material column includes a plurality of embedded metal wires, the plurality of embedded metal wires are distributed in the dielectric material columns, aligning in the longitudinal direction of the dielectric material columns, and the locations of the embedded metal wires may be not be defined;
b) integrating the plurality of dielectric material columns into an ingot of dielectric material columns by using a matrix material to encase and connect the plurality of dielectric material columns from their sides;
c) slicing the ingot of dielectric material columns along the direction perpendicular to the embedded metal wires into a plurality of pieces so as to form a plurality of inhomogeneous core layers with each including a plurality of dielectric core units connected together from sides through the matrix material, each dielectric core unit including a plurality of dark through core vias (dTCV), wherein the locations of the plurality of dTCV may not be defined;
d) stacking two dielectric layers with each on one surface of the inhomogeneous core layer;
e) forming a desired number of openings in each region of the two dielectric layers corresponding to each dielectric core unit, the openings in each region of the upper dielectric layer and the openings in each region of the lower dielectric layer form a number of pairs of openings, each pair of openings are the same in size and shape, align from the upper to lower surfaces of each dielectric core unit, and locate at the desired position for forming a desired eTSV; the size of each pair of openings is bigger than the space among the dTCV embedded in the dielectric core unit so that there is at least one dTCV between each pair of openings, the space between any two neighboring openings on the same surface is bigger than the size of each dTCV so that any two neighboring openings on the same surface are not connected by the same dTCV;
f) stacking two metal layers with each on one surface of the inhomogeneous core layer, covering the two dielectric layers and filling the openings in the two dielectric layers, wherein the portions of the metal layers filled inside the openings of the two dielectric layers form the desired pattern of eTSV in each region corresponding to each dielectric core unit, resulting in a panel of substrate core having a plurality of substrate core units and each substrate core unit having a desired pattern of eTSV.

14. The method for making a panel of substrate core of claim 12, further comprising the processing step: h) stacking one or more dielectric layers, one or more circuit layers and one terminal layer over the pattern of eTSV on one surface of the panel of substrate core, and stacking at least one terminal layer over the pattern of eTSV on the other surface of the panel of substrate core so as to form a panel of IC chip package substrate based on the panel of substrate core.

15. The method for making a panel of substrate core of claim 13, wherein the two metal layers may be further processed as a pattern of metal layers including the pattern of eTSV consisting of the metals in the openings of the dielectric layers and a number of circuits consisting of the metals outside the openings of the dielectric layers.

16. The method for making a panel of substrate core of claim 15, further comprising the processing step: g) stacking one or more dielectric layers, one or more circuit layers and one terminal layer over the pattern of eTSV on one surface of the panel of substrate core, and stacking at least one terminal layer over the pattern of eTSV on the other surface of the panel of substrate core so as to form a panel of IC chip package substrate.

17. The method for making a panel of substrate core of 14, further comprising the processing step: i) sawing the panel of IC chip package substrate along the sawing streets among the plurality of dielectric core units into a plurality of IC chip package substrate units having a pattern of eTSV.

18. The method for making a panel of substrate core of 16, further comprising the processing step: h) sawing the panel of IC chip package substrate along the sawing streets among the plurality of dielectric core units into a plurality of IC chip package substrate units having a pattern of eTSV.
